(19) United States
(12) Patent Application Publication
(10) Pub. No.: US 2026/0182387 A1
(43) Pub. Date: Jun. 25, 2026

(54) MICROELECTRONIC DEVICE COMPRISING AN UNCLONABLE PHYSICAL FUNCTION AND ASSOCIATED MANUFACTURING METHOD

(71) Applicant: COMMISSARIAT À L’ENERGIE ATOMIQUE ET AUX ENERGIES ALTERNATIVES, PARIS (FR)

(72) Inventors: Christelle CHARPIN-NICOLLE, GRENOBLE CEDEX (FR); Florian PEBAY-PEYROULA, GRENOBLE CEDEX (FR)

(21) Appl. No.: 19/423,452

(22) Filed: Dec. 17, 2025

(30) Foreign Application Priority Data
Dec. 19, 2024 (FR) FR2414590

(51) Int. Cl. H10W 42/40; H10B 63/00; H10N 70/00; H10N 70/20

(52) U.S. Cl. CPC H10W 42/40; H10B 63/80; H10N 70/063; H10N 70/24

(57) ABSTRACT

A microelectronic device includes a plurality of resistive memory points, a first part of the resistive memory points being resistive memory points configured to form a so-called PUF zone of the device, a second part of the resistive memory points being configured to form a so-called memory zone of the device, each resistive memory point including a first electrode layer, a second electrode layer, and an active layer of resistive memory included between the first and second electrode layers, wherein each resistive memory point of the PUF zone includes a carbon layer with a thickness greater than or equal to 3 nanometres, which extends between the first electrode layer and the active layer.

### FIELD OF THE INVENTION

The present invention generally relates to the field of microelectronics. It more particularly relates to the field of microelectronic devices comprising an unclonable physical function.

One object of the invention is a microelectronic device comprising an unclonable physical function as well as a storage memory. Another object of the invention is the method for obtaining the device according to the invention.

### STATE OF THE ART

Counterfeiting of integrated electronic circuits, or “chips”, is a major problem today. The fight against chip counterfeiting is a major challenge for the microelectronics industry.

To fight counterfeiting, solutions are being sought to authenticate a circuit in order to distinguish whether it is a legitimate circuit, that is, a successful authentication, or a counterfeit circuit, that is, a failed authentication. A first method consists in using a unique identifier for each circuit and have a database of legitimate identifiers. But it turns out that it is very easy to emulate—or replay—a valid identifier by virtue of a hardware or software virus. The unique identifier is therefore not a viable solution as it does not protect against replay attacks.

Another mechanism, widely used in the field of information security, is the so-called “challenge-response” mechanism. This mechanism allows authentication to be made while protecting against replay attacks. A user who wants to authenticate a device using this mechanism has to perform the following steps:
the user generates a random number N, where N is the challenge;
The user sends N to the circuit.
the circuit calculates R=F(N) from a secret function F, R being the response;
The circuit responds with R to the user.
the user compares R with the expected response and, if they match, authentication is successful.

For the challenge-response method to be applicable to a given device, the manufacturer has to carry out a so-called “enrolment” step at the factory, consisting in building a database containing legitimate “challenge-response” pairs for the given device. In practical terms, for each integrated circuit, the tester will generate a number of challenges N, send them to the circuit, retrieve each response R and record the N-R pairs in a database. Throughout the life cycle of the chip, a user will be able to authenticate the integrated circuit by carrying out the following steps:
they request a challenge N from the database from the manufacturer;
the chip calculates the response R=F(N);
The user or manufacturer compares this response with that stored in the data base.
The challenge-response pair is deleted from the database to avoid any replay.

This authentication takes place via a secure protocol between the database and the integrated circuit. The authentication solution is based on one essential element: function F. This function has to be unique to each chip and unclonable. This is referred to as a Physical Unclonable Function (PUF), as an attacker should not be able to physically recreate the function, otherwise they would be able to create a legitimate clone of the PUF and therefore of the circuit.

A PUF function therefore has to have several characteristics, among which a manufacturing process that achieves very high inter-chip variability and low intra-chip variability.

Existing PUF functions are based on random physical elements. For example, one of the very first PUFs (non-silicon) is based on air bubbles found in molten plastic.

Several techniques have been provided for obtaining PUFs in the field of microelectronics. For example, there may be mentioned techniques being performed at the integrated circuit package, such as coating PUFs or magnetic PUFs based on the random distribution of resistive or magnetic particles.

Other techniques are performed at the component and are essentially based on the dispersion of physical characteristics. Among the integrated circuits including a PUF function known to those skilled in the art are those that make use of signal propagation times, such as ring circuits or arbiter circuits. Alternatively, it is possible to make use of start-up instabilities, for example in Static Random-Access Memory (SRAM)-type devices.

A well-known implementation of PUF technology in the field of resistive memories is described in the publication “Error-free Physically Unclonable Function (PUF) with programmed ReRAM using reliable resistance states by Novel ID-Generation method” (Tseng et al.—International Conference on Solid State Devices and Materials 2017). This is based on the use of a matrix of rewritable non-volatile resistive memories (ReRAM), such as memories including an active zone with metal oxides (OxRAM or “Oxide Resistive RAM”). These memories are resistive type memories, that is, they can have at least two resistive states, corresponding to a High Resistance State (HRS) and a Low Resistance State (LRS), when a voltage is applied. The voltage required to switch from an HRS state to an LRS state corresponds to the formation of a conductive filament connecting the two electrodes of each resistive memory point and is also referred to as the “forming” voltage when referring to the first voltage applied to form the memory point. Subsequently, the voltage is said to be the “set” voltage to switch the memory from an HRS state to an LRS state.

The method known to those skilled in the art consists in applying a given range of voltages and, due to the dispersion of the physical parameters of the memory points, a random matrix of formed and non-formed memory points is obtained.

Although this method makes it possible to obtain a PUF function in a ReRAM memory plane, its implementation is complicated due to the very narrow window for interrupting the formation of memory points. This risks greatly reducing the randomness of the PUF device, thereby increasing the risk of counterfeiting.

There is therefore a need to provide a microelectronic device integrating a PUF function and a storage memory function that is reliable and simple to make, while being very difficult to counterfeit.

### SUMMARY OF THE INVENTION

The aim of the invention is to at least partially solve the above-mentioned problems by providing a microelectronic device including two different composition parts, one intended for the PUF part of the device and ensuring a high dispersion of the physical parameters of the memory points, the other intended for the storage memory part of the device and ensuring the highest possible repeatability of memory performance and the lowest possible dispersion of performance.

To this end, a first object of the invention is a microelectronic device comprising a plurality of resistive memory points, a first part of said resistive memory points being resistive memory points configured to provide an unclonable physical function, the resistive memory points of said first part forming a so-called “PUF” zone of the device, a second part of said resistive memory points being configured to provide a memory function to the microelectronic device, the resistive memory points of the second part forming a so-called “memory” zone of the device, each resistive memory point comprising a first electrode layer, a second electrode layer, and an active layer of resistive memory comprised between the first and second electrode layers, said microelectronic device being characterised in that each resistive memory point of the first part forming the PUF zone comprises a carbon layer with a thickness greater than or equal to 3 nanometres which extends between the first electrode layer and the active layer.

It is meant by part of the support corresponding to the PUF memory points, the part of the device to provide the PUF function. This part of the device is also called the PUF zone or the PUF part of the device. The storage memory is also called the memory zone or the non-PUF zone of the device.

By integrating a carbon layer with a thickness greater than or equal to 3 nanometres between the first electrode layer and the active layer of the resistive memory points of the PUF zone, the microelectronic device according to the invention increases the dispersion of resistances before and after forming. This increased dispersion is essential for generating robust, unclonable PUF functions, making each device unique and difficult to clone. Indeed, greater dispersion means that resistance values are less predictable and less likely to be replicated. This is made possible by the presence of the carbon layer in the PUF zone, which leads to greater variability in the electrical properties of the memory points. This carbon layer is then not found in the memory zone.

The device according to the invention further allows the forming voltage window to be widened for the use of a ReRAM memory plane as a PUF device. As a result, by applying a forming voltage in this widened window, it is possible to obtain the formation of substantially half of the resistive memory points in the PUF zone, obtaining good response diversity in the PUF zone of the device.

In other words, the invention makes it possible to widen the window of the forming voltage curve by lowering its slope. This will enable 50% of formed memory points and 50% of non-formed memory points within a matrix to be aimed at and thus good PUF diversity to be obtained.

The device according to the invention makes it possible to avoid the lengthy step of searching for the forming voltage disclosed, for example, in the article by Tseng et al. “Error-free Physically Unclonable Function (PUF) with programmed ReRAM using reliable resistance states by Novel ID-Generation method”. Indeed, by virtue of the invention, dispersion of forming voltages in the PUF zone is very high, which facilitates the search for the forming voltage necessary to obtain the formation condition of substantially 50% of the resistive memory points in the PUF zone.

Further to the characteristics just discussed in the preceding paragraphs, the microelectronic device according to the invention may have one or more of the following additional characteristics, considered individually or according to any technically possible combination:
the active layer is an active oxide layer.
the carbon layer has a thickness less than or equal to 5 nanometres.
each resistive memory point of the second part forming the memory zone does not comprise a carbon layer with a thickness greater than or equal to 3 nanometres between the first electrode layer and the active layer.
each resistive memory point of the second part forming the memory zone does not comprise a carbon layer between the first electrode layer and the active layer.
each resistive memory point is non-formed.
The first electrode layer is of titanium nitride, doped silicon, doped polysilicon, tungsten, tungsten nitride, molybdenum nitride, tantalum nitride, cobalt silicide, nickel silicide, palladium silicide, platinum silicide, titanium silicide, other silicides, nickel, platinum, iridium, ruthenium, or any combination thereof, the second electrode layer is of titanium nitride, doped silicon, doped polysilicon, tungsten, tungsten nitride, molybdenum nitride, tantalum nitride, cobalt silicide, nickel silicide, palladium silicide, platinum silicide, titanium silicide, other silicides, nickel, platinum, iridium, ruthenium, or any combination thereof, and the active layer comprises at least one hafnium layer.

Another object of the invention is a method for manufacturing a microelectronic device comprising a plurality of resistive memory points, a first part of said resistive memory points being resistive memory points configured to provide an unclonable physical function, the resistive memory points of said first part forming a so-called “PUF” zone of the device, a second part of said resistive memory points being configured to provide a memory function to the microelectronic device, the resistive memory points of the second part forming a so-called “memory” zone of the device, said manufacturing method being characterised in that it comprises:
Providing a support comprising a first electrode layer;
Depositing a carbon layer onto the first electrode layer;
Removing the carbon layer in the memory zone;
Depositing an active layer of resistive memory;
Depositing at least a second electrode layer;
Etching the second electrode layer, the active layer and the first electrode layer so as to define the plurality of resistive memory points.

Further to the characteristics just discussed in the preceding paragraphs, the manufacturing method according to another aspect of the invention may have one or more additional characteristics from among the following, considered individually or according to all technically possible combinations:
removing the carbon layer in the memory zone comprises:
   depositing a protective layer configured to protect the PUF zone of the device;
   etching the memory zone of the device to remove the carbon layer in the memory zone of the device.
etching in the memory zone of the device is plasma etching.
The method further comprises a step of encapsulating the memory points using at least one dielectric layer.
The method according to the invention comprises a step of re-establishing contacts on both electrodes.

Advantageously, the device according to the invention includes resistive memory points in the memory part having very low dispersion of the physical properties, ensuring good operation as a storage memory.

### LIST OF FIGURES

Further characteristics and advantages of the invention will clearly appear from the description given below, by way of indicating and in no way limiting purposes, with reference to the appended figures, in which:

FIG. 1 schematically illustrates a microelectronic device according to the invention.

FIG. 2A and FIG. 2B schematically illustrate memory points seen in a cross-section view of memory points of a microelectronic device according to the invention.

FIG. 3 schematically illustrates resistance dispersions before and after forming in a device of prior art.

FIG. 4 schematically illustrates resistance dispersions before and after forming in devices according to the invention.

FIG. 5 schematically illustrates a comparison of resistance dispersions before and after annealing in devices according to the invention.

FIG. 6 schematically illustrates a method for manufacturing a microelectronic device according to the invention.

### DETAILED DESCRIPTION OF THE INVENTION

The aim of the present invention is to enhance the resistance dispersion of the PUF zones of the resistive memories. This increased dispersion is essential for generating robust, unclonable PUF functions, making each device unique and difficult to clone. At the same time, the memory zone of the device, devoid of this carbon layer, maintains a low dispersion of resistances, thereby ensuring stable and repeatable performance of the storage memories.

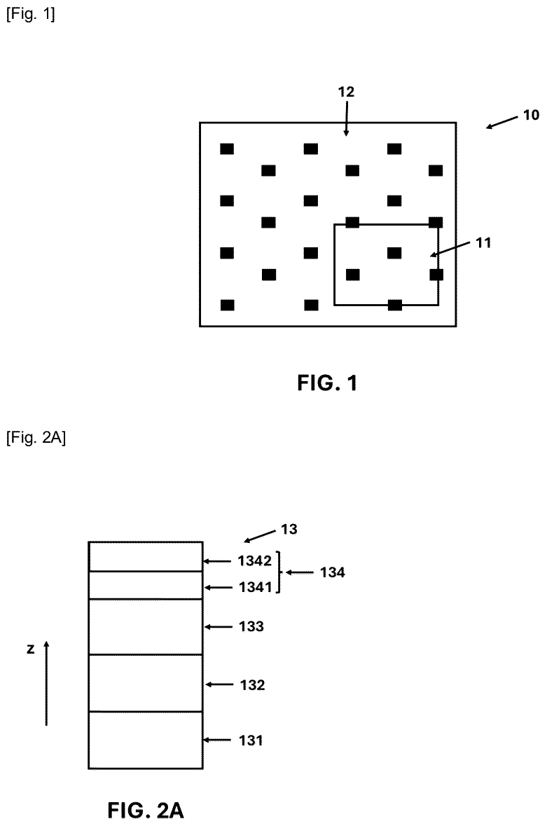

FIG. 1 represents an example microelectronic device 10 according to the invention.

The device 10 according to the invention comprises a zone 11 comprising a plurality of resistive memory points to provide a PUF function and a zone 12 comprising a plurality of resistive memory points to provide a memory function.

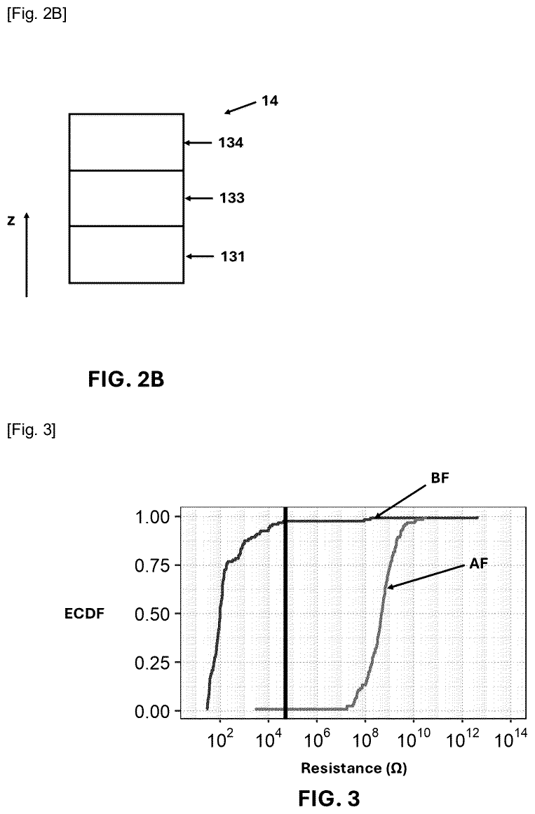

FIGS. 2A and 2B each represent an example memory point of a microelectronic device 10 according to the invention in a cross-section view. As is visible in FIGS. 2A and 2B, each memory point is in the form of a stack of layers which extends along an axis z. The layers 131 to 134 form the different layers of each stack. The different layers extend in parallel to each other (and in parallel to a substrate, not represented, on which each memory point rests). The axis z is herein perpendicular to the plane of the different layers of the stack forming each memory point.

In FIG. 2A is represented a memory point 13 in the PUF zone 11, and in FIG. 2B is represented a memory point 14 in the memory zone 12.

The memory point 13 is a memory point in the PUF zone 11 and comprises a first electrode 131, a second electrode 134, a carbon layer 132 and an active layer 133, the carbon layer 132 and the active layer 133 being disposed between the first electrode 131 and the second electrode 134.

The first electrode 131 forms a lower electrode of the memory point 13. The second electrode 134 forms an upper electrode of the memory point 13. By convention, the terms “lower” and “upper” are used in relation to the substrate on which each memory point is manufactured. Thus, a lower layer of each memory point will refer to a layer close to the substrate, while an upper layer will refer to a layer opposite to and remote from the substrate.

The first electrode 131 is formed of a conductive inert material. This conductive material is in particular neutral with respect to oxygen atoms. The first electrode 2 comprises, for example, a metal material. It comprises, herein, titanium nitride (TiN). Alternatively, the first electrode 133 may be of titanium nitride, doped silicon, doped polysilicon, tungsten, tungsten nitride, molybdenum nitride, tantalum nitride, cobalt silicide, nickel silicide, palladium silicide, platinum silicide, titanium silicide, other silicides, nickel, platinum, iridium, ruthenium or other suitable materials, or any suitable combination of the preceding materials.

The first electrode 131 has, for example, a thickness of between 5 and 200 nanometres (nm).

According to the invention, and as previously indicated, the memory point 13 comprises a carbon layer 132. This carbon layer 132, which is only present in the memory points 13 of the PUF 11 zone, makes it possible to obtain an increased resistance dispersion in the memory points 13 of the PUF zone 11. The carbon layer 132 is disposed on the first electrode 131, that is, in contact with the first electrode 131.

The carbon layer has a thickness greater than or equal to 3 nanometres. Preferably, the carbon layer 132 also has a thickness less than or equal to 5 nanometres.

The active layer 133 is disposed on the carbon layer 132, that is, in contact with the carbon layer 132. The active layer 133 is a layer of active material, preferably active oxide.

The active layer 133 comprises a metal oxide or a semiconductor oxide. Preferably herein, the active layer 133 is based on hafnium dioxide HfO₂. In the present description, it is meant by the term “based on”, that the layer in question comprises more than 50% of the element mentioned after this term (for example, herein, it means that the active layer 133 comprises more than 50% of hafnium dioxide). The active layer 133 may also be a bi-layer, with a hafnium layer and a layer of another material, for example, aluminium dioxide Al2O3, tantalum dioxide Ta2O5, zirconium dioxide ZrO2, titanium dioxide TiO2, hafnium oxide denoted as HfOx with x>=1.8, or any other suitable material.

Alternatively, the active layer 133 may comprise tantalum (V) oxide Ta₂O₅ or any other metal oxide known to make such an active layer.

The active layer 133 has, for example, a thickness of at least 3 nm and is preferably between 3 and 10 nm.

In another embodiment, the active layer 133 may comprise a layer of active material as previously described, and an additional dielectric oxide layer.

The dielectric oxide layer is adapted to serve as a support for forming an electrically conductive filament, which passes through the active layer from one side to the other to electrically connect the first electrode 131 to the second electrode 134. This electrically conductive filament can be broken and then successively reformed several times during successive write and erase (RESET) cycles of the memory point. In practice, this conductive filament is produced for the first time during a kind of controlled electrical breakdown of the active layer (according to a usual so-called “forming” operation.

The dielectric oxide layer comprises, for example, a metal oxide or a semiconductor oxide. Preferably, it is an aluminium oxide Al₂O₃. Alternatively, it may also be silicon dioxide SiO₂.

The dielectric oxide layer has, for example, a thickness of between 0.2 and 2 nm.

As shown in FIG. 2A, the second electrode 134 (or upper electrode) is disposed on the active layer 133. It is, for example, in the form of a bilayer structure. It comprises, for example, a first conductive layer 1341 and a second conductive layer 1342.

The second conductive layer 1342 is disposed on the first conductive layer 1341. The second conductive layer 1342 is formed of a conductive material comprising a transition metal. This conductive material is, for example, titanium nitride TiN. Alternatively, the second electrode 134 may be of titanium nitride, doped silicon, doped polysilicon, tungsten, tungsten nitride, molybdenum nitride, tantalum nitride, cobalt silicide, nickel silicide, palladium silicide, platinum silicide, titanium silicide, other silicides, nickel, platinum, iridium, ruthenium or other suitable materials, or any suitable combination of the preceding materials.

The second conductive layer 1342 has a thickness of between 5 and 200 nm.

The second conductive layer 1342 comprises, for example, a plurality of conductive layers.

The second conductive layer 1342 acts both as a protective layer (especially preventing total oxidation of the first conductive layer 1341) and as a contact layer for electrically connecting the memory point 13 to its electronic driving and reading circuit.

The first conductive layer 1341 is disposed on the active layer 133. It is in direct contact with the active layer 133.

The first conductive layer 1341 has the distinctive feature of being a layer adapted to create oxygen vacancies in the active layer 133 when this first conductive layer 1341 is in contact with the active layer 133. According to the commonly used Anglo-Saxon term, the first conductive layer is an “oxygen scavenging layer”-type layer.

The first conductive layer 1341 comprises a metal conductive material. Preferably, it comprises titanium Ti, tantalum Ta or hafnium Hf.

For example, when the second conductive layer 1342 comprises titanium nitride, the first conductive layer 1341 is formed of a conductive material selected from titanium Ti or hafnium Hf.

Alternatively, when the second conductive layer 1342 comprises tantalum nitride, the first conductive layer 1341 is formed of a conductive material selected from tantalum Ta or hafnium Hf.

Still alternatively, when the second conductive layer 1342 comprises tungsten, the first conductive layer 1341 is formed of a conductive material selected from titanium Ti, tantalum Ta or hafnium Hf.

For example, the thickness of the first conductive layer 1341 is between 3 and 20 nm.

The memory point 14 represented in FIG. 2B is a memory point of the memory zone 12 and comprises a first electrode 131, a second electrode 134 and an active layer 133 disposed between the first electrode 131 and the second electrode 134. Thus, the description of the layers 131, 133 and 134 of the memory point 13 also applies to the memory point 14. Differently from the memory point 13, the memory point 14 does not comprise a carbon layer 132. Thus, none of the memory points 14 in the memory zone 12 comprises a carbon layer 132, unlike the memory points 13 in the PUF zone 11, which all comprise a carbon layer 132. This makes it possible to obtain a device 10 that includes both a PUF function and a storage memory function.

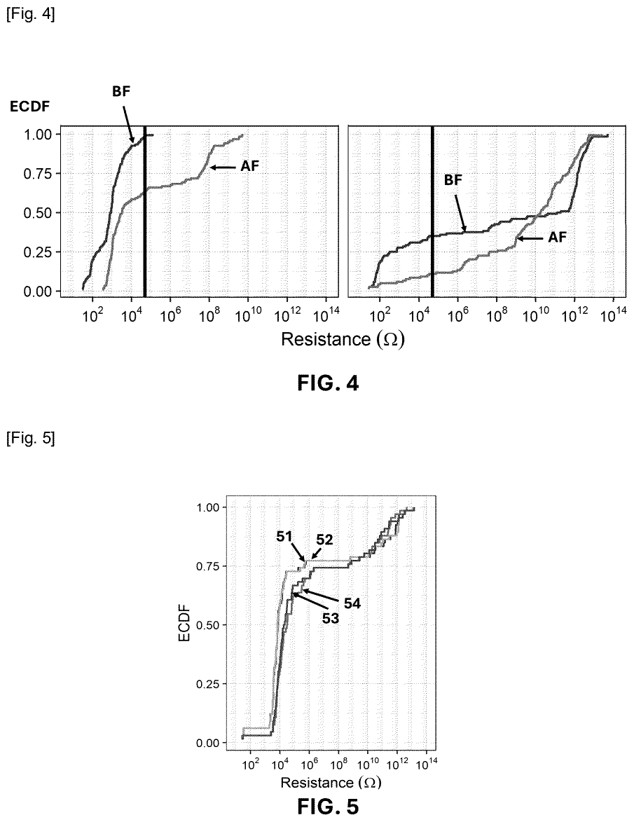

Tests have been conducted to obtain the resistance dispersions with and without a carbon layer. The results of these tests are represented in FIGS. 3 and 4.

FIG. 3 shows a schematic representation of the cumulative distribution of the resistance values obtained, illustrated by an empirical cumulative distribution function (ECDF), for a memory point in the memory zone, that is, without a carbon layer 132.

FIG. 4 shows two schematic representations of the cumulative distribution of the resistance values obtained, illustrated by an empirical cumulative distribution function (ECDF), on the left for a memory point in the PUF 11 zone comprising a carbon layer 132 with a thickness of 3 nanometres and on the right for a memory point in the PUF 11 zone comprising a carbon layer 132 with a thickness of 5 nanometres.

In each of the representations of FIGS. 3 and 4, the curve “BF” represents the cumulative distribution of the resistances of the memory points of the device 10 according to the invention after forming, that is, after applying a forming voltage, thus when the memory points are formed.

In each of the representations of FIGS. 3 and 4, the curve “AF” represents the cumulative distribution of the resistances of the memory points of the device 10 according to the invention before forming, that is, before applying a forming voltage, thus when the memory points are non-formed.

The stacks used had an upper electrode 134 of titanium nitride TIN, a lower electrode of titanium Ti of 5 nm coated with titanium nitride TIN, and an active layer of hafnium HfO2 doped with silicon Si of 5 nm.

As represented in FIG. 4, the resistance before forming AF in the left part (with the layer C of 3 nanometres) is much more dispersed than in FIG. 3 (without the layer C), since the resistance distribution extends from 5*10² Ohms to 10¹⁰ Ohms, whereas in FIG. 3, the resistance distribution extends from 10⁷ Ohms to 10¹⁰ Ohms. Likewise, the resistance before forming AF in the right part (with the layer C of 5 nanometres) is much more dispersed than in FIG. 3 (without the layer C), since the resistance distribution ranges from 10 Ohms to 10¹³ Ohms.

To use the PUF function, a low voltage is simply to be applied to a memory point, for example in the order of 0.1 to 0.2 volts, and the associated resistance to be read. This voltage should be low enough not to change the state of the memory point, that is, not to cause a transition between the resistive states (HRS for “High Resistance state” and LRS for “Low Resistance State”).

As represented in FIG. 4, the resistance after forming BF in the right part (with the layer C of 5 nanometres) is much more dispersed than in FIG. 3 (without the layer C), since the resistance distribution extends from 10 Ohms to 10¹³ Ohms, whereas in FIG. 3, the resistance distribution after forming extends from 10 Ohms to 5*10⁴ Ohms.

Thus, the invention even allows the PUF function of the device 10 to be used before the memory points have been formed, that is, before forming, and therefore before a forming voltage is applied, a forming voltage being, for example, in the order of 1 to 5V. Indeed, before forming, as represented by the curves AF, BF, the resistances are also highly dispersed, which is particularly remarkable in the case of a carbon layer 132 with a thickness of 5 nanometres. This increased dispersion therefore makes it possible to use the PUF function of the microelectronic device 10 before and after forming, unlike in prior art, in which the dispersion of the resistances before forming is too concentrated.

It has also been noticed, as represented in FIG. 5, that the dispersions obtained hardly change over time after annealing at 150° Celsius for 1 hour.

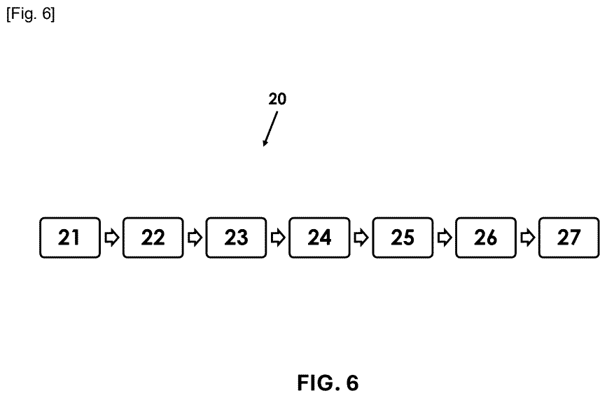

The present invention also relates to a method for manufacturing a microelectronic device 10. FIG. 6 represents, as a flowchart, an example manufacturing method according to the invention.

The method 20 according to the invention comprises a step 21 of providing a support comprising a first electrode layer 131. The first electrode layer 131 is the first layer of the resistive memory points. The support is common to the PUF zone 11 and the memory zone 12 of the device 10. According to one embodiment, the step 201 comprises depositing the first electrode layer 131, for example by PVD (Physical Vapor Deposition). The first electrode layer 131 may, for example, be in the form of vias, or be etched at the same time as the upper electrode, the active layer, and the lower electrode.

According to the invention, the method 20 comprises a second step 22 of depositing a carbon layer 132 onto the first electrode layer 131. Deposition 22 is preferably carried out by PVD. This carbon layer 132 is, for example, deposited onto the entire support provided in step 201.

The carbon layer deposited has a thickness greater than or equal to 3 nanometres. The carbon layer 132 deposited in step 22 has, for example, a thickness less than or equal to 5 nanometres.

The method 20 according to the invention comprises a step 23 of removing the carbon layer 132 in the memory area 12 of the device 10. For this, the PUF zone 11 is protected. Thus, step 23 comprises a sub-step 23a of protecting the part of the support corresponding to the PUF zone of the device 10. Advantageously, this protection step then allows the carbon layer to be selectively removed from the memory zone 12 during a sub-step 23b.

According to one embodiment, sub-step 23a is a lithography step comprising spreading a resin, exposing it using a mask and stripping the resin once etching has been carried out in sub-step 23b. Advantageously, sub-step 23a allows the PUF zone 11, for which the carbon layer should not be removed during the etching sub-step 23b, to be covered with a resin layer.

Removing the carbon layer 132 is carried out by etching in sub-step 23b. According to one embodiment, the etching sub-step 23b in the memory zone 12 of the device 10 is performed using plasma etching. The resin is then removed. Thus, at the end of step 23, a carbon layer 132 is present only in the part of the support corresponding to the PUF zone 11 of the device 10, and is absent from the part of the support corresponding to the memory zone 12 of the device 10.

The method 20 according to the invention further comprises a step 24 of depositing the active layer 133 onto the entire substrate, that is, onto the lower electrode layer 131 in the part of the support corresponding to the memory zone 12, and onto the carbon layer 132 in the part of the support corresponding to the PUF zone 11. According to one embodiment, this step comprises depositing a hafnium layer HfO2, for example by Atomic Layer Deposition (ALD) or by PVD.

The method 20 according to the invention further includes a step 25 of depositing a second electrode layer 134, for example by PVD. According to one embodiment, this step includes depositing a layer of Ti or TiN or both.

The method 20 according to the invention further includes a step 26 of etching the second electrode layer 134, the active layer 133, the carbon layer 132 when present, and then the first electrode layer 131, so as to define the plurality of resistive memory points.

Advantageously, this step makes it possible to obtain the resistive memory points of the PUF zone 11 and the resistive memory points of the memory zone 12.

The method 20 according to the invention further comprises a step of encapsulating 27 the memory points using a dielectric layer.

According to one embodiment, the encapsulating step 27 comprises encapsulating in several dielectric layers. Examples of dielectric materials used in step 27 are SiN and SiO₂.

During steps 24 of depositing the active layer 133, 25 of the second electrode layer 134 or upper electrode, and then 26 of defining the memory points, the two PUF 11 and memory 12 zones are treated identically, with the deposition of the materials constituting the active layer 133, for example HfO2, the upper electrode 134, example Ti, TiN, and the definition of the patterns constituting the memory points throughout the cell. According to one embodiment, an SiN-type dielectric serving as a hard mask may also be used during the lithography step.

Finally, according to one embodiment, vias may be used to re-establish the contacts on the memory points of the PUF zone 11 and the memory zone 12.

1. A microelectronic device comprising a plurality of resistive memory points, a first part of said resistive memory points being resistive memory points configured to provide an unclonable physical function, the resistive memory points of said first part forming a PUF zone of the device, a second part of said resistive memory points being configured to provide a memory function to the microelectronic device, the resistive memory points of the second part forming a memory zone of the device, each resistive memory point comprising a first electrode layer, a second electrode layer, and an active layer of resistive memory comprised between the first and second electrode layers, said microelectronic device being characterised in that each resistive memory point of the first part forming the PUF zone comprises a carbon layer with a thickness greater than or equal to 3 nanometres which extends between the first electrode layer and the active layer.

2. The microelectronic device according to claim 1, wherein the active layer is an oxide-based layer.

3. The microelectronic device according to claim 1, wherein the carbon layer has a thickness less than or equal to 5 nanometres.

4. The microelectronic device according to claim 1, wherein each resistive memory point of the second part forming the memory zone does not comprise a carbon layer between the first electrode layer and the active layer.

5. The microelectronic device according to claim 1, wherein each resistive memory point is non-formed.

6. The microelectronic device according to claim 1, wherein the first electrode layer is of titanium nitride, doped silicon, doped polysilicon, tungsten, tungsten nitride, molybdenum nitride, tantalum nitride, cobalt silicide, nickel silicide, palladium silicide, platinum silicide, titanium silicide, other silicides, nickel, platinum, iridium, ruthenium, or any combination thereof, the second electrode layer is of titanium nitride, doped silicon, doped polysilicon, tungsten, tungsten nitride, molybdenum nitride, tantalum nitride, cobalt silicide, nickel silicide, palladium silicide, platinum silicide, titanium silicide, other silicides, nickel, platinum, iridium, ruthenium, or any combination thereof, and wherein the active layer comprises at least one hafnium layer.

7. A method for manufacturing a microelectronic device comprising a plurality of resistive memory points, a first part of said resistive memory points being resistive memory points configured to provide an unclonable physical function, the resistive memory points of said first part forming a PUF zone of the device, a second part of said resistive memory points being configured to provide a memory function to the microelectronic device, the resistive memory points of the second part forming a memory zone of the device, said manufacturing method comprising:
providing a support comprising a first electrode layer;
depositing a carbon layer onto the first electrode layer;
Removing the carbon layer in the memory zone;
depositing an active layer of resistive memory;
depositing at least a second electrode layer;
etching the second electrode layer, the active layer and the first electrode layer so as to define the plurality of resistive memory points.

8. The method for manufacturing a microelectronic device according to claim 7, wherein removing the carbon layer in the memory zone comprises:
depositing a protective layer configured to protect the PUF zone of the device;
etching the memory zone of the device to remove the carbon layer in the memory zone of the device.

9. The method for manufacturing a microelectronic device according to claim 8, wherein etching in the memory zone of the device is plasma etching.

10. The method for manufacturing a microelectronic device according to claim 1, further comprising a step of encapsulating the memory points using at least one dielectric layer.
